(19) United States
(12) Patent Application Publication
(10) Pub. No.: US 2010/0227272 A1
(43) Pub. Date: Sep. 9, 2010

(54) Highly Functional Multiphoton Curable Reactive Species

(75) Inventors: Robert J. DeVoe, Arden Hills, MN (US); Guoping Mao, Woodbury, MN (US)

Correspondence Address: 3M INNOVATIVE PROPERTIES COMPANY, PO BOX 33427, ST. PAUL, MN, 55133-3427, US

(73) Assignee: INNOVATIVE PROPERTIES COMPANY

(21) Appl. No.: 12/682,155

(22) PCT Filed: Sep. 9, 2008
(86) PCT No.: PCT/US08/75715

§ 371 Date: Apr. 8, 2010

Related U.S. Application Data
(60) Provisional application No. 60/979,229, filed on Oct. 11, 2007.

(51) Int. Cl. G03F 7/004; G03F 7/20

(52) U.S. Cl. 430/270.1; 430/322; 430/325

(57) ABSTRACT

A multiphoton curable photoreactive composition including hydantoin hexaacrylate and a photoinitiator system. In some embodiments, the multiphoton curable photoreactive composition consists essentially of hydantoin hexaacrylate and a photoinitiator system. Additionally, the applying a multiphoton curable photoreactive composition comprising hydantoin hexaacrylate and a photoinitiator system may be applied to a substrate and a portion of the multiphoton curable photoreactive composition may be at least partially cured to form an at least partially cured structure.

### TECHNICAL FIELD

The invention relates to curable compositions. More specifically, the invention relates to curable compositions that possess high photosensitivity and desirable durability and are suitable for use in multiphoton curing processes.

### BACKGROUND

In multiphoton induced curing processes, which are described in, for example, U.S. Pat. No. 6,855,478, incorporated herein by reference, a layer including a multiphoton curable photoreactive composition is applied on a substrate such as, for example, a silicon wafer, and cured using a focused light source such as a laser beam. The multiphoton curable photoreactive composition in the applied layer includes at least one reactive species that is capable of undergoing an acid or radical initiated chemical reaction, as well as a multiphoton initiator system. Typical multiphoton photoreactive compositions include a mixture of reactive components chosen to provide desired properties upon curing. Image-wise exposure of the layer with light of an appropriate wavelength and sufficient intensity causes two-photon (or three-photon, etc.) absorption in the multiphoton initiator system, which induces in the reactive species an acid or radical initiated chemical reaction in a region of the layer that is exposed to the light. This chemical reaction causes crosslinking, polymerization, or a change in solubility characteristics in the exposed region, referred to herein as curing, to form a cured object. Following the curing step, the layer may optionally be developed by removing a non-cured portion of the layer to obtain the cured object, or by removing the cured object itself from the layer.

Multiphoton absorption has the advantage that the probability of absorption does not scale linearly with intensity, as in single-photon absorption. For example, in two-photon absorption, the probability scales quadratically with intensity, and in three-photon absorption, the probability scales cubically with intensity. Thus, three-dimensional resolution is possible using multiphoton absorption and a focused light source.

In some cases, multiphoton curing is used to create a master that is then used to make a tool for use in replication of the originally cured structure. This typically requires additional steps after development, including electroplating the at least partially cured structure or structures to form the tool. The tool is then typically further manipulated to produce a mold that may be used to produce replicates of the originally cured structure.

### SUMMARY

In general, the invention is directed to multiphoton curable photoreactive compositions that possess high photosensitivity and desirable properties, such as high durability, upon curing.

In one aspect, the invention is directed to a multiphoton curable photoreactive composition including hydantoin hexaacrylate and a photoinitiator system.

In some embodiments, the photoinitiator system includes at least one multiphoton photosensitizer, at least one photoinitiator (or electron acceptor), and, optionally, at least one electron donor.

In another aspect, the invention is directed to a multiphoton curable photoreactive composition consisting essentially of hydantoin hexaacrylate and a photoinitiator system.

In some embodiments, the photoinitiator system includes at least one multiphoton photosensitizer, at least one photoinitiator (or electron acceptor), and, optionally, at least one electron donor.

In yet another aspect, the invention is directed to a method including applying a multiphoton curable photoreactive composition including hydantoin hexaacrylate and a photoinitiator system to a substrate, and at least partially curing a portion of the multiphoton curable photoreactive composition to form an at least partially cured structure.

In some embodiments, the photoinitiator system includes at least one multiphoton photosensitizer, at least one photoinitiator (or electron acceptor), and, optionally, at least one electron donor.

In certain embodiments, the method further includes developing the at least partially cured structure by removing at least a portion of any uncured multiphoton curable photoreactive composition.

The invention may provide advantages. For example, the cured structure may be used directly as a mold from which parts may be reproduced. This may avoid undesirable intermediate steps between the formation of the master by multiphoton absorption and the production of the desired item via replication.

As another example, including a hexa-functional or greater acrylate in a multiphoton curable photoreactive composition may increase the photosensitivity of the composition. This may allow the use of a lower power light source or a higher scanning speed, both of which may increase the throughput of a multiphoton curing system.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a schematic diagram illustrating an apparatus suitable for effecting multiphoton absorption.

FIGS. 2A and 2B are top-view and perspective view scanning electron microscope (SEM) images of structures formed using a prior art multiphoton curable photoreactive composition.

FIGS. 3A and 3B are top-view and perspective view scanning electron microscope (SEM) images of structures formed using a multiphoton curable photoreactive composition of the current invention.

FIGS. 4A and 4B are top-view and perspective view scanning electron microscope (SEM) images of structures formed using a prior art multiphoton curable photoreactive composition.

FIGS. 5A and 5B are top-view and perspective view scanning electron microscope (SEM) images of structures formed using a multiphoton curable photoreactive composition of the current invention.

### DETAILED DESCRIPTION

In general, the invention is directed to multiphoton curable photoreactive compositions that possess high photosensitivity and desirable properties, such as high durability, upon curing. Multiphoton curable photoreactive compositions typically include a reactive species and a photoinitiator system. Each of the components will be discussed in detail below.

### Reactive Species

Reactive species suitable for use in the photoreactive compositions include those that cure upon exposure to light sufficient to cause multiphoton absorption. As used in this disclosure, “cure” means to effect polymerization and/or to effect crosslinking in the composition, or a change in solubility characteristics in an exposed region of the composition.

Reactive species which are suitable for use in multiphoton curable photoreactive compositions preferably possess one or more desirable characteristics. For example, suitable reactive species may possess high photosensitivity. Photosensitivity refers to the rate, or alternatively the extent, of chemical reaction upon exposure to light of sufficient intensity to initiate the reaction. For example, a reactive species with a relatively high photosensitivity may react to a further extent than a reactive species with low photosensitivity, under the same intensity of light. Alternatively, a reactive species with a relatively high photosensitivity, when exposed to light of lesser intensity, may react to the same extent as a reactive species with a relatively low photosensitivity. By either definition, high photosensitivity is desirable, as it may allow either the use of a lower intensity light source, the use of a higher scanning rate, or both, and thus may facilitate a higher throughput of a multiphoton fabrication system.

Another desirable characteristic includes a minimal change in refractive index upon exposure to the light beam. Because multiphoton curing processes scan a tightly focused light beam in three dimensions to create the desired structure, any change in the refractive index of the reactive species upon curing may decrease the precision with which the light beam is focused due to refraction at the interface of the two materials with different refractive indices.

Yet another desirable characteristic includes minimal swelling and deformation during solvent development. Swelling may be due to absorption of the developing solvent, and deformation may be due to the forces caused by fluid flow, or capillary forces as the structure is removed from the solvent. Both swelling and deformation during solvent development decrease the fidelity of the cured structure to the desired shape. For example, swelling may cause an increase in volume, which may lead to adjacent structures contacting each other. As another example, swelling may obscure or destroy features such as channels, apertures, slits, and the like. Swelling may be caused by incomplete curing upon exposure to the light beam. The incompletely cured reactive species acts as a “solvent” for the developing solvent, and absorbs more solvent that a fully cured reactive species would. Swelling may also be caused by a low crosslink density, that is, a low number of crosslinks per unit volume, which is proportional to the number of functional groups per molecule.

Deformation of the structure during solvent development may be caused by the forces due to solvent flow. Deformation may cause adjacent structures to contact each other. A higher crosslink density may lead to a higher elastic modulus, and a stronger structure. Thus, a reactive species having both high photosensitivity, to ensure complete curing, and a high crosslink density, to minimize swelling and deformation, is particularly desirable.

A high crosslink density also contributes to desirable strength and durability after development. Sufficiently high strength and durability may allow the developed structure to be utilized directly as a manufacturing tool. The manufacturing tool may be, for example, a mold insert for use in injection molding, compression molding, polymerization within a mold, extrusion and the like. The manufacturing tool preferably possesses sufficient strength and durability to withstand the repeated high temperatures and pressures of injection molding, for example. High crosslink density, then, contributes to the strength and durability of the cured manufacturing tool.

It is also desirable that the photoreactive composition include a single reactive species. The use of a single reactive species may provide, for example, a more reproducible composition with a desired chemical makeup, which in turn provides a cured reaction product with more reproducible properties.

One preferred single reactive species includes acrylic functionality. Acrylic functional groups may be generally represented as:

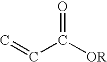

where R is any known side group, for example, alkane, alkene, alkyne, ester, ether, carboxylic acid, cyclic alkane, aromatic, and the like.

Preferred reactive species include molecules with multiple acrylic functional groups on each molecule, more preferably about 5 or more acrylic groups per molecule, most preferably about 6 acrylic groups per molecule. Particularly preferred molecules with acrylic functional groups include hydantoin hexaacrylate (HHA). In some embodiments, the reactive species in the multiphoton curable photoreactive composition consists essentially of HHA. That is, the reactive species includes HHA and any impurities associated with the manufacture or use of HHA, but does not include any other reactive species. The synthesis and chemical structure of HHA is described below in Example 1.

Multiphoton curable photoreactive compositions may also optionally include other reactive species such as, for example, addition-polymerizable monomers and oligomers and addition-crosslinkable polymers (such as free-radically polymerizable or crosslinkable ethylenically-unsaturated species including, for example, acrylates, methacrylates, and certain vinyl compounds such as styrenes), as well as cationically-polymerizable monomers and oligomers and cationically-crosslinkable polymers (which species are most commonly acid-initiated and which include, for example, epoxies, vinyl ethers, cyanate esters, etc.), and the like, and mixtures thereof.

Suitable ethylenically-unsaturated species are described, for example, by Palazzotto et al. in U.S. Pat. No. 5,545,676 at column 1, line 65, through column 2, line 26, and include mono-, di-, and poly-acrylates and methacrylates (for example, methyl acrylate, methyl methacrylate, ethyl acrylate, isopropyl methacrylate, n-hexyl acrylate, stearyl acrylate, allyl acrylate, glycerol diacrylate, glycerol triacrylate, ethyleneglycol diacrylate, diethyleneglycol diacrylate, triethyleneglycol dimethacrylate, 1,3-propanediol diacrylate, 1,3-propanediol dimethacrylate, trimethylolpropane triacrylate, 1,2,4-butanetriol trimethacrylate, 1,4-cyclohexanediol diacrylate, pentaerythritol triacrylate, pentaerythritol tetraacrylate, pentaerythritol tetramethacrylate, sorbitol hexacrylate, bis[1-(2-acryloxy)]-p-ethoxyphenyldimethylmethane, bis[1-(3-acryloxy-2-hydroxy)]-p-propoxyphenyldimethylmethane, trishydroxyethyl-isocyanurate trimethacrylate, the bis-acrylates and bis-methacrylates of polyethylene glycols of molecular weight about 200-500, copolymerizable mixtures of acrylated monomers such as those of U.S. Pat. No. 4,652,274, and acrylated oligomers such as those of U.S. Pat. No. 4,642,126); unsaturated amides (for example, methylene bis-acrylamide, methylene bis-methacrylamide, 1,6-hexamethylene bis-acrylamide, diethylene triamine tris-acrylamide and beta-methacrylaminoethyl methacrylate); vinyl compounds (for example, styrene, diallyl phthalate, divinyl succinate, divinyl adipate, and divinyl phthalate); and the like; and mixtures thereof. Suitable reactive polymers include polymers with pendant (meth)acrylate groups, for example, having from 1 to about 50 (meth)acrylate groups per polymer chain. Examples of such polymers include aromatic acid (meth)acrylate half ester resins such as Sarbox™ resins available from Sartomer (for example, Sarbox™ 400, 401, 402, 404, and 405). Other useful reactive polymers curable by free radical chemistry include those polymers that have a hydrocarbyl backbone and pendant peptide groups with free-radically polymerizable functionality attached thereto, such as those described in U.S. Pat. No. 5,235,015 (Ali et al.). Mixtures of two or more monomers, oligomers, and/or reactive polymers can be used if desired. Preferred ethylenically-unsaturated species include acrylates, aromatic acid (meth)acrylate half ester resins, and polymers that have a hydrocarbyl backbone and pendant peptide groups with free-radically polymerizable functionality attached thereto.

Suitable cationically-reactive species are described, for example, by Oxman et al. in U.S. Pat. Nos. 5,998,495 and 6,025,406 and include epoxy resins. Such materials, broadly called epoxides, include monomeric epoxy compounds and epoxides of the polymeric type and can be aliphatic, alicyclic, aromatic, or heterocyclic. These materials generally have, on the average, at least 1 polymerizable epoxy group per molecule (preferably, at least about 1.5 and, more preferably, at least about 2). The polymeric epoxides include linear polymers having terminal epoxy groups (for example, a diglycidyl ether of a polyoxyalkylene glycol), polymers having skeletal oxirane units (for example, polybutadiene polyepoxide), and polymers having pendant epoxy groups (for example, a glycidyl methacrylate polymer or copolymer). The epoxides can be pure compounds or can be mixtures of compounds containing one, two, or more epoxy groups per molecule. These epoxy-containing materials can vary greatly in the nature of their backbone and substituent groups. For example, the backbone can be of any type and substituent groups thereon can be any group that does not substantially interfere with cationic cure at room temperature. Illustrative of permissible substituent groups include halogens, ester groups, ethers, sulfonate groups, siloxane groups, nitro groups, phosphate groups, and the like. The molecular weight of the epoxy-containing materials can vary from about 58 to about 100,000 or more.

Other epoxy-containing materials that are useful include glycidyl ether monomers of the formula

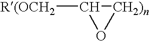

where R′ is alkyl or aryl and n is an integer of 1 to 8. Examples are glycidyl ethers of polyhydric phenols obtained by reacting a polyhydric phenol with an excess of a chlorohydrin such as epichlorohydrin (for example, the diglycidyl ether of 2,2-bis-(2,3-epoxypropoxyphenol)-propane). Additional examples of epoxides of this type are described in U.S. Pat. No. 3,018,262, and in Handbook of Epoxy Resins, Lee and Neville, McGraw-Hill Book Co., New York (1967).

A number of commercially available epoxy monomers or resins can be used. Epoxides that are readily available include, but are not limited to, octadecylene oxide; epichlorohydrin; styrene oxide; vinylcyclohexene oxide; glycidol; glycidyl methacrylate; diglycidyl ethers of bisphenol A (for example, those available under the trade designations “EPON 815C”, “EPON 813”, “EPON 828”, “EPON 1004F”, and “EPON 1001F” from Hexion Specialty Chemicals, Inc., Columbus, Ohio); and diglycidyl ether of bisphenol F (for example, those available under the trade designations “ARALDITE GY281” from Ciba Specialty Chemicals Holding Company, Basel, Switzerland, and “EPON 862” from Hexion Specialty Chemicals, Inc.). Other aromatic epoxy resins include the SU-8 resins available from MicroChem. Corp., Newton, Mass.

Other exemplary epoxy monomers include vinyl cyclohexene dioxide (available from SPI Supplies, West Chester, Pa.); 4-vinyl-1-cylcohexene diepoxide (available from Aldrich Chemical Co., Milwaukee, Wis.); 3,4-epoxycyclohexylmethyl-3,4-epoxycyclohexene carboxylate (for example, one available under the trade designation “CYRACURE UVR-6110” from Dow Chemical Co., Midland, Mich.); 3,4-epoxy-6-methylcylcohexylmethyl-3,4-epoxy-6-methyl-cylcohexane carboxylate; 2-(3,4-epoxycyclohexyl-5,5-spiro-3,4-epoxy)cyclohexane-metadioxane; bis(3,4-epoxycyclohexylmethyl)adipate (for example, one available under the trade designation “CYRACURE UVR-6128” from Dow Chemical Co.); bis(3,4-epoxy-6-methylclyclohexylmethyl)adipate; 3,4-epoxy-6-methylcyclohexane carboxylate; and dipentene dioxide.

Still other exemplary epoxy resins include epoxidized polybutadiene (for example, one available under the trade designation “POLY BD 605E” from Sartomer Co., Inc., Exton, Pa.); epoxy silanes (for example, 3,4-epoxycylclohexylethyltrimethoxysilane and 3-glycidoxypropyltrimethoxysilane, commercially available from Aldrich Chemical Co., Milwaukee, Wis.); flame retardant epoxy monomers (for example, one available under the trade designation “DER-542”, a brominated bisphenol type epoxy monomer available from Dow Chemical Co., Midland, Mich.); 1,4-butanediol diglycidyl ether (for example, one available under the trade designation “ARALDITE RD-2” from Ciba Specialty Chemicals); hydrogenated bisphenol A-epichlorohydrin based epoxy monomers (for example, one available under the trade designation “EPONEX 1510” from Hexion Specialty Chemicals, Inc.); polyglycidyl ether of phenol-formaldehyde novolak (for example, one available under the trade designation “DEN-431” and “DEN-438” from Dow Chemical Co.); and epoxidized vegetable oils such as epoxidized linseed and soybean oils available under the trade designations “VIKOLOX” and “VIKOFLEX” from Atofina Chemicals (Philadelphia, Pa.).

Additional suitable epoxy resins include alkyl glycidyl ethers commercially available from Hexion Specialty Chemicals, Inc. (Columbus, Ohio) under the trade designation “HELOXY”. Exemplary monomers include “HELOXY MODIFIER 7” (a C8-C10 alky glycidyl ether), “HELOXY MODIFIER 8” (a C12-C14 alkyl glycidyl ether), “HELOXY MODIFIER 61” (butyl glycidyl ether), “HELOXY MODIFIER 62” (cresyl glycidyl ether), “HELOXY MODIFIER 65” (p-tert-butylphenyl glycidyl ether), “HELOXY MODIFIER 67” (diglycidyl ether of 1,4-butanediol), “HELOXY 68” (diglycidyl ether of neopentyl glycol), “HELOXY MODIFIER 107” (diglycidyl ether of cyclohexanedimethanol), “HELOXY MODIFIER 44” (trimethylol ethane triglycidyl ether), “HELOXY MODIFIER 48” (trimethylol propane triglycidyl ether), “HELOXY MODIFIER 84” (polyglycidyl ether of an aliphatic polyol), and “HELOXY MODIFIER 32” (polyglycol diepoxide).

Other useful epoxy resins comprise copolymers of acrylic acid esters of glycidol (such as glycidyl acrylate and glycidyl methacrylate) with one or more copolymerizable vinyl compounds. Examples of such copolymers are 1:1 styrene-glycidyl methacrylate and 1:1 methyl methacrylate-glycidyl acrylate. Other useful epoxy resins are well known and contain such epoxides as epichlorohydrins, alkylene oxides (for example, propylene oxide), styrene oxide, alkenyl oxides (for example, butadiene oxide), and glycidyl esters (for example, ethyl glycidate).

Useful epoxy-functional polymers include epoxy-functional silicones such as those described in U.S. Pat. No. 4,279,717 (Eckberg et al.), which are commercially available from the General Electric Company. These are polydimethylsiloxanes in which 1-20 mole % of the silicon atoms have been substituted with epoxyalkyl groups (preferably, epoxy cyclohexylethyl, as described in U.S. Pat. No. 5,753,346 (Leir et al.).

Blends of various epoxy-containing materials can also be utilized. Such blends can comprise two or more weight average molecular weight distributions of epoxy-containing compounds (such as low molecular weight (below 200), intermediate molecular weight (about 200 to 1000), and higher molecular weight (above about 1000)). Alternatively or additionally, the epoxy resin can contain a blend of epoxy-containing materials having different chemical natures (such as aliphatic and aromatic) or functionalities (such as polar and non-polar). Other cationically-reactive polymers (such as vinyl ethers and the like) can additionally be incorporated, if desired.

Preferred epoxies include aromatic glycidyl epoxies (for example, the EPON resins available from Hexion Specialty Chemicals, Inc. and the SU-8 resins available from MicroChem. Corp., Newton, Mass., including XP KMPR 1050 strippable SU-8), and the like, and mixtures thereof. More preferred are the SU-8 resins and mixtures thereof.

Suitable rationally-reactive species also include vinyl ether monomers, oligomers, and reactive polymers (for example, methyl vinyl ether, ethyl vinyl ether, tert-butyl vinyl ether, isobutyl vinyl ether, triethyleneglycol divinyl ether (RAPI-CURE DVE-3, available from International Specialty Products, Wayne, N.J.), trimethylolpropane trivinyl ether, and the VECTOMER divinyl ether resins from Morflex, Inc., Greensboro, N.C. (for example, VECTOMER 1312, VECTOMER 4010, VECTOMER 4051, and VECTOMER 4060 and their equivalents available from other manufacturers)), and mixtures thereof. Blends (in any proportion) of one or more vinyl ether resins and/or one or more epoxy resins can also be utilized. Polyhydroxy-functional materials (such as those described, for example, in U.S. Pat. No. 5,856,373 (Kaisaki et al.)) can also be utilized in combination with epoxy- and/or vinyl ether-functional materials.

Non-curable species include, for example, reactive polymers whose solubility can be increased upon acid- or radical-induced reaction. Such reactive polymers include, for example, aqueous insoluble polymers bearing ester groups that can be converted by photogenerated acid to aqueous soluble acid groups (for example, poly(4-tert-butoxycarbonyloxystyrene). Non-curable species also include the chemically-amplified photoresists described by R. D. Allen, G. M. Wallraff, W. D. Hinsberg, and L. L. Simpson in “High Performance Acrylic Polymers for Chemically Amplified Photoresist Applications,” J. Vac. Sci. Technol. B, 9, 3357 (1991). The chemically-amplified photoresist concept is now widely used for microchip manufacturing, especially with sub-0.5 micron (or even sub-0.2 micron) features. In such photoresist systems, catalytic species (typically hydrogen ions) can be generated by irradiation, which induces a cascade of chemical reactions. This cascade occurs when hydrogen ions initiate reactions that generate more hydrogen ions or other acidic species, thereby amplifying reaction rate. Examples of typical acid-catalyzed chemically-amplified photoresist systems include deprotection (for example, t-butoxycarbonyloxystyrene resists as described in U.S. Pat. No. 4,491,628, tetrahydropyran (THP) methacrylate-based materials, THP-phenolic materials such as those described in U.S. Pat. No. 3,779,778, t-butyl methacrylate-based materials such as those described by R. D Allen et al. in Proc. SPIE 2438, 474 (1995), and the like); depolymerization (for example, polyphthalaldehyde-based materials); and rearrangement (for example, materials based on the pinacol rearrangements).

If desired, mixtures of different types of reactive species can be utilized in the photoreactive compositions. For example, mixtures of free-radically-reactive species and cationically-reactive species are also useful.

### Photoinitiator System

The photoinitiator system is a multiphoton photoinitiator system, as the use of such a system enables polymerization to be confined or limited to the focal region of a focused beam of light. Such a system preferably is a two- or three-component system that comprises at least one multiphoton photosensitizer, at least one photoinitiator (or electron acceptor), and, optionally, at least one electron donor. Such multi-component systems can provide enhanced sensitivity, enabling photoreaction to be effected in a shorter period of time and thereby reducing the likelihood of problems due to movement of the sample and/or one or more components of the exposure system.

Preferably, the multiphoton photoinitiator system comprises photochemically effective amounts of (a) at least one multiphoton photosensitizer that is capable of simultaneously absorbing at least two photons and that, optionally but preferably, has a two-photon absorption cross-section greater than that of fluorescein; (b) optionally, at least one electron donor compound different from the multiphoton photosensitizer and capable of donating an electron to an electronic excited state of the photosensitizer; and (c) at least one photoinitiator that is capable of being photosensitized by accepting an electron from an electronic excited state of the photosensitizer, resulting in the formation of at least one free radical and/or acid.

Alternatively, the multiphoton photoinitiator system can be a one-component system that comprises at least one photoinitiator. Photoinitiators useful as one-component multi-photon photoinitiator systems include acyl phosphine oxides (for example, those sold by Ciba under the trade name Irgacure™ 819, as well as 2,4,6 trimethyl benzoyl ethoxyphenyl phosphine oxide sold by BASF Corporation under the trade name Lucirin™ TPO-L) and stilbene derivatives with covalently attached sulfonium salt moeities (for example, those described by W. Zhou et al. in Science 296, 1106 (2002)). Other conventional ultraviolet (UV) photoinitiators such as benzil ketal can also be utilized, although their multi-photon photoinitiation sensitivities will generally be relatively low.

Multiphoton photosensitizers, electron donors, and photoinitiators (or electron acceptors) useful in two- and three-component multiphoton photoinitiator systems are described below.

(1) Multiphoton Photosensitizers

Multiphoton photosensitizers suitable for use in the multiphoton photoinitiator system of the photoreactive compositions are those that are capable of simultaneously absorbing at least two photons when exposed to sufficient light. Preferably, the photosensitizers have a two-photon absorption cross-section greater than that of fluorescein (that is, greater than that of 3′,6′-dihydroxyspiro[isobenzofuran-1(3H), 9′-(9H)xanthen]-3-one). Generally, the preferred cross-section can be greater than about 50×10⁻⁵⁰ cm⁴ sec/photon, as measured by the method described by C. Xu and W. W. Webb in J. Opt. Soc. Am. B, 13, 481 (1996) (which is referenced by Marder and Perry et al. in International Publication No. WO 98/21521 at page 85, lines 18-22).

More preferably, the two-photon absorption cross-section of the photosensitizer is greater than about 1.5 times that of fluorescein (or, alternatively, greater than about 75×10⁻⁵⁰ cm⁴ sec/photon, as measured by the above method); even more preferably, greater than about twice that of fluorescein (or, alternatively, greater than about 100×10⁻⁵⁰ cm⁴ sec/photon); most preferably, greater than about three times that of fluorescein (or, alternatively, greater than about 150×10⁻⁵⁰ cm⁴ sec/photon); and optimally, greater than about four times that of fluorescein (or, alternatively, greater than about 200×10⁻⁵⁰ cm⁴ sec/photon).

Preferably, the photosensitizer is soluble in the reactive species (if the reactive species is liquid) or is compatible with the reactive species and with any optional binders (as described below) that are included in the composition. Most preferably, the photosensitizer is also capable of sensitizing 2-methyl-4,6-bis(trichloromethyl)-s-triazine under continuous irradiation in a wavelength range that overlaps the single photon absorption spectrum of the photosensitizer (single photon absorption conditions), using the test procedure described in U.S. Pat. No. 3,729,313.

Preferably, a photosensitizer can also be selected based in part upon shelf stability considerations. Accordingly, selection of a particular photosensitizer can depend to some extent upon the particular reactive species utilized (as well as upon the choices of electron donor compound and/or photoinitiator).

Particularly preferred multiphoton photosensitizers include those exhibiting large multiphoton absorption cross-sections, such as Rhodamine B (that is, N-[9-(2-carboxyphenyl)-6-(diethylamino)-3H-xanthen-3-ylidene]-N-ethylethanaminium chloride or hexafluoroantimonate) and the four classes of photosensitizers described, for example, by Marder and Perry et al. in International Patent Publication Nos. WO 98/21521 and WO 99/53242. The four classes can be described as follows: (a) molecules in which two donors are connected to a conjugated π (pi)-electron bridge; (b) molecules in which two donors are connected to a conjugated π (pi)-electron bridge which is substituted with one or more electron accepting groups; (c) molecules in which two acceptors are connected to a conjugated π (pi)-electron bridge; and (d) molecules in which two acceptors are connected to a conjugated π (pi)-electron bridge which is substituted with one or more electron donating groups (where “bridge” means a molecular fragment that connects two or more chemical groups, “donor” means an atom or group of atoms with a low ionization potential that can be bonded to a conjugated π (pi)-electron bridge, and “acceptor” means an atom or group of atoms with a high electron affinity that can be bonded to a conjugated π (pi)-electron bridge).

The four above-described classes of photosensitizers can be prepared by reacting aldehydes with ylides under standard Wittig conditions or by using the McMurray reaction, as detailed in International Patent Publication No. WO 98/21521.

Other compounds are described by Reinhardt et al. (for example, in U.S. Pat. Nos. 6,100,405, 5,859,251, and 5,770,737) as having large multiphoton absorption cross-sections, although these cross-sections were determined by a method other than that described above.

Preferred photosensitizers include the following compounds (and mixtures thereof):

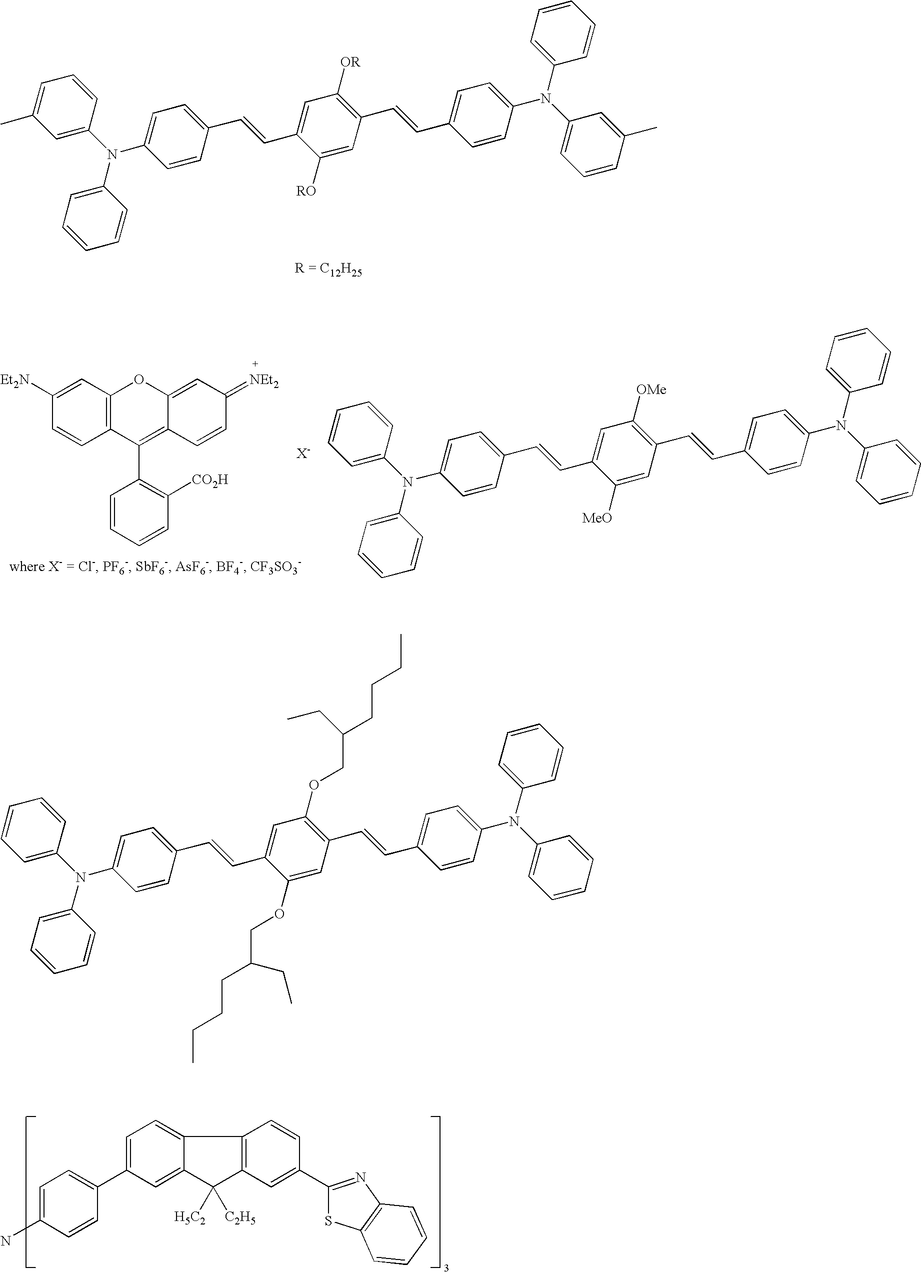

(2) Electron Donor Compounds

Electron donor compounds useful in the multiphoton photoinitiator system of the photoreactive compositions are those compounds (other than the photosensitizer itself) that are capable of donating an electron to an electronic excited state of the photosensitizer. Such compounds may be used, optionally, to increase the multiphoton photosensitivity of the photoinitiator system, thereby reducing the exposure required to effect photoreaction of the photoreactive composition. The electron donor compounds preferably have an oxidation potential that is greater than zero and less than or equal to that of p-dimethoxybenzene. Preferably, the oxidation potential is between about 0.3 and 1 volt versus a standard saturated calomel electrode (“S.C.E.”).

The electron donor compound is also preferably soluble in the reactive species and is selected based in part upon shelf stability considerations (as described above). Suitable donors are generally capable of increasing the speed of cure or the image density of a photoreactive composition upon exposure to light of the desired wavelength.

When working with cationically-reactive species, those skilled in the art will recognize that the electron donor compound, if of significant basicity, can adversely affect the cationic reaction. (See, for example, the discussion in U.S. Pat. No. 6,025,406 (Oxman et al.) at column 7, line 62, through column 8, line 49.)

In general, electron donor compounds suitable for use with particular photosensitizers and photoinitiators can be selected by comparing the oxidation and reduction potentials of the three components (as described, for example, in U.S. Pat. No. 4,859,572 (Farid et al.)). Such potentials can be measured experimentally (for example, by the methods described by R. J. Cox, Photographic Sensitivity, Chapter 15, Academic Press (1973)) or can be obtained from references such as N. L. Weinburg, Ed., Technique of Electroorganic Synthesis Part II Techniques of Chemistry, Vol. V (1975), and C. K. Mann and K. K. Barnes, Electrochemical Reactions in Nonaqueous Systems (1970). The potentials reflect relative energy relationships and can be used to guide electron donor compound selection.

Suitable electron donor compounds include, for example, those described by D. F. Eaton in Advances in Photochemistry, edited by B. Voman et al., Volume 13, pp. 427-488, John Wiley and Sons, New York (1986); by Oxman et al. in U.S. Pat. No. 6,025,406 at column 7, lines 42-61; and by Palazzotto et al. in U.S. Pat. No. 5,545,676 at column 4, line 14 through column 5, line 18. Such electron donor compounds include amines (including triethanolamine, hydrazine, 1,4-diazabicyclo[2.2.2]octane, triphenylamine (and its triphenylphosphine and triphenylarsine analogs), aminoaldehydes, and aminosilanes), amides (including phosphoramides), ethers (including thioethers), ureas (including thioureas), sulfinic acids and their salts, salts of ferrocyanide, ascorbic acid and its salts, dithiocarbamic acid and its salts, salts of xanthates, salts of ethylene diamine tetraacetic acid, salts of (alkyl)ₙ(aryl)ₘborates (n+m=4) (tetraalkylammonium salts preferred), various organometallic compounds such as SnR₄ compounds (where each R is independently chosen from among alkyl, aralkyl (particularly, benzyl), aryl, and alkaryl groups) (for example, such compounds as n-C₃H₇Sn(CH₃)₃, (allyl)Sn(CH₃)₃, and (benzyl)Sn(n-C₃H₇)₃), ferrocene, and the like, and mixtures thereof. The electron donor compound can be unsubstituted or can be substituted with one or more non-interfering substituents. Particularly preferred electron donor compounds contain an electron donor atom (such as a nitrogen, oxygen, phosphorus, or sulfur atom) and an abstractable hydrogen atom bonded to a carbon or silicon atom alpha to the electron donor atom.

Preferred amine electron donor compounds include alkyl-, aryl-, alkaryl- and aralkyl-amines (for example, methylamine, ethylamine, propylamine, butylamine, triethanolamine, amylamine, hexylamine, 2,4-dimethylaniline, 2,3-dimethylaniline, o-, m- and p-toluidine, benzylamine, aminopyridine, N,N′-dimethylethylenediamine, N,N′-diethylethylenediamine, N,N′-dibenzylethylenediamine, N,N′-diethyl-1,3-propanediamine, N,N′-diethyl-2-butene-1,4-diamine, N,N′-dimethyl-1,6-hexanediamine, piperazine, 4,4′-trimethylenedipiperidine, 4,4′-ethylenedipiperidine, p-N,N-dimethyl-aminophenethanol and p-N-dimethylaminobenzonitrile); aminoaldehydes (for example, p-N,N-dimethylaminobenzaldehyde, p-N,N-diethylaminobenzaldehyde, 9-julolidine carboxaldehyde, and 4-morpholinobenzaldehyde); and aminosilanes (for example, trimethylsilylmorpholine, trimethylsilylpiperidine, bis(dimethylamino)diphenylsilane, tris(dimethylamino)methylsilane, N,N-diethylaminotrimethylsilane, tris(dimethylamino)phenylsilane, tris(methylsilyl)amine, tris(dimethylsilyl)amine, bis(dimethylsilyl)amine, N,N-bis(dimethylsilyl)aniline, N-phenyl-N-dimethylsilylaniline, and N,N-dimethyl-N-dimethylsilylamine); and mixtures thereof. Tertiary aromatic alkylamines, particularly those having at least one electron-withdrawing group on the aromatic ring, have been found to provide especially good shelf stability. Good shelf stability has also been obtained using amines that are solids at room temperature. Good photosensitivity has been obtained using amines that contain one or more julolidinyl moieties.

Preferred amide electron donor compounds include N,N-dimethylacetamide, N,N-diethylacetamide, N-methyl-N-phenylacetamide, hexamethylphosphoramide, hexaethylphosphoramide, hexapropylphosphoramide, trimorpholinophosphine oxide, tripiperidinophosphine oxide, and mixtures thereof.

Preferred alkylarylborate salts include

Ar₃B⁻(n-C₄H₉)N⁺(C₂H₅)₄

Ar₃B⁻(n-C₄H₉)N⁺(CH₃)₄

Ar₃B⁻(n-C₄H₉)N⁺(n-C₄H₉)₄

Ar₃B⁻(n-C₄H₉)Li⁺

Ar₃B⁻(n-C₄H₉)N⁺(C₆H₁₃)₄

Ar₃B⁻—(C₄H₉)N⁺(CH₃)₃(CH₂)₂CO₂(CH₂)₂CH₃

Ar₃B⁻—(C₄H₉)N⁺(CH₃)₃(CH₂)₂OCO(CH₂)₂CH₃

Ar₃B⁻-(sec-C₄H₉)N⁺(CH₃)₃(CH₂)₂CO₂(CH₂)₂CH₃

Ar₃B⁻-(sec-C₄H₉)N⁺(C₆H₁₃)₄

Ar₃B⁻—(C₄H₉)N⁺(C₈H₁₇)₄

Ar₃B⁻—(C₄H₉)N⁺(CH₃)₄

(p-CH₃O—C₆H₄)₃B⁻(n-C₄H₉)N⁺(n-C₄H₉)₄

Ar₃B⁻—(C₄H₉)N⁺(CH₃)₃(CH₂)₂OH

ArB⁻(n-C₄H₉)₃N⁺(CH₃)₄

ArB⁻(C₂H₅)₃N⁺(CH₃)₄

Ar₂B⁻(n-C₄H₉)₂N⁺(CH₃)₄

Ar₃B⁻(C₄H₉)N⁺(C₄H₉)₄

Ar₄B⁻N⁺(C₄H₉)₄

ArB⁻(CH₃)₃N⁺(CH₃)₄

(n-C₄H₉)₄B⁻N⁺(CH₃)₄

Ar₃B⁻(C₄H₉)P⁺(C₄H₉)₄

(where Ar is phenyl, naphthyl, substituted (preferably, fluoro-substituted) phenyl, substituted naphthyl, and like groups having greater numbers of fused aromatic rings), as well as tetramethylammonium n-butyltriphenylborate and tetrabutylammonium n-hexyl-tris(3-fluorophenyl)borate, and mixtures thereof.

Suitable ether electron donor compounds include 4,4′-dimethoxybiphenyl, 1,2,4-trimethoxybenzene, 1,2,4,5-tetramethoxybenzene, and the like, and mixtures thereof. Suitable urea electron donor compounds include N,N′-dimethylurea, N,N-dimethylurea, N,N′-diphenylurea, tetramethylthiourea, tetraethylthiourea, tetra-n-butylthiourea, N,N-di-n-butylthiourea, N,N′-di-n-butylthiourea, N,N-diphenylthiourea, N,N′-diphenyl-N,N′-diethylthiourea, and the like, and mixtures thereof.

Preferred electron donor compounds for free radical-induced reactions include amines that contain one or more julolidinyl moieties, alkylarylborate salts, and salts of aromatic sulfinic acids. However, for such reactions, the electron donor compound can also be omitted, if desired (for example, to improve the shelf stability of the photoreactive composition or to modify resolution, contrast, and reciprocity). Preferred electron donor compounds for acid-induced reactions include 4-dimethylaminobenzoic acid, ethyl 4-dimethylaminobenzoate, 3-dimethylaminobenzoic acid, 4-dimethylaminobenzoin, 4-dimethylaminobenzaldehyde, 4-dimethylaminobenzonitrile, 4-dimethylaminophenethyl alcohol, and 1,2,4-trimethoxybenzene.

(3) Photoinitiators

Suitable photoinitiators (that is, electron acceptor compounds) for the reactive species of the photoreactive compositions are those that are capable of being photosensitized by accepting an electron from an electronic excited state of the multiphoton photosensitizer, resulting in the formation of at least one free radical and/or acid. Such photoinitiators include iodonium salts (for example, diaryliodonium salts), sulfonium salts (for example, triarylsulfonium salts optionally substituted with alkyl or alkoxy groups, and optionally having 2,2′ oxy groups bridging adjacent aryl moieties), and the like, and mixtures thereof.

The photoinitiator is preferably soluble in the reactive species and is preferably shelf-stable (that is, does not spontaneously promote reaction of the reactive species when dissolved therein in the presence of the photosensitizer and the electron donor compound). Accordingly, selection of a particular photoinitiator can depend to some extent upon the particular reactive species, photosensitizer, and electron donor compound chosen, as described above. If the reactive species is capable of undergoing an acid-initiated chemical reaction, then the photoinitiator is an onium salt (for example, an iodonium or sulfonium salt).

Suitable iodonium salts include those described by Palazzotto et al. in U.S. Pat. No. 5,545,676 at column 2, lines 28 through 46. Suitable iodonium salts are also described in U.S. Pat. Nos. 3,729,313, 3,741,769, 3,808,006, 4,250,053 and 4,394,403. The iodonium salt can be a simple salt (for example, containing an anion such as Cl⁻, Br⁻, I⁻ or C₄H₅SO₃⁻) or a metal complex salt (for example, containing SbF₆⁻, PF₆⁻, BF₄⁻, tetrakis(perfluorophenyl)borate, SbF₅OH⁻ or AsF₆⁻). Mixtures of iodonium salts can be used if desired.

Examples of useful aromatic iodonium complex salt photoinitiators include diphenyliodonium tetrafluoroborate; di(4-methylphenyl)iodonium tetrafluoroborate; phenyl-4-methylphenyliodonium tetrafluoroborate; di(4-heptylphenyl)iodonium tetrafluoroborate; di(3-nitrophenyl)iodonium hexafluorophosphate; di(4-chlorophenyl)iodonium hexafluorophosphate; di(naphthyl)iodonium tetrafluoroborate; di(4-trifluoromethylphenyl)iodonium tetrafluoroborate; diphenyliodonium hexafluorophosphate; di(4-methylphenyl)iodonium hexafluorophosphate; diphenyliodonium hexafluoroarsenate; di(4-phenoxyphenyl)iodonium tetrafluoroborate; phenyl-2-thienyliodonium hexafluorophosphate; 3,5-dimethylpyrazolyl-4-phenyliodonium hexafluorophosphate; diphenyliodonium hexafluoroantimonate; 2,2′-diphenyliodonium tetrafluoroborate; di(2,4-dichlorophenyl)iodonium hexafluorophosphate; di(4-bromophenyl)iodonium hexafluorophosphate; di(4-methoxyphenyl)iodonium hexafluorophosphate; di(3-carboxyphenyl)iodonium hexafluorophosphate; di(3-methoxycarbonylphenyl)iodonium hexafluorophosphate; di(3-methoxysulfonylphenyl)iodonium hexafluorophosphate; di(4-acetamidophenyl)iodonium hexafluorophosphate; di(2-benzothienyl)iodonium hexafluorophosphate; and diphenyliodonium hexafluoroantimonate; and the like; and mixtures thereof. Aromatic iodonium complex salts can be prepared by metathesis of corresponding aromatic iodonium simple salts (such as, for example, diphenyliodonium bisulfate) in accordance with the teachings of Beringer et al., J. Am. Chem. Soc. 81, 342 (1959).

Preferred iodonium salts include diphenyliodonium salts (such as diphenyliodonium chloride, diphenyliodonium hexafluorophosphate, and diphenyliodonium tetrafluoroborate), diaryliodonium hexafluoroantimonate (for example, SarCat™ SR 1012 available from Sartomer Company), and mixtures thereof.

Useful sulfonium salts include those described in U.S. Pat. No. 4,250,053 (Smith) at column 1, line 66, through column 4, line 2, which can be represented by the formulas:

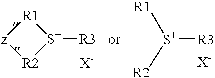

wherein R₁, R₂, and R₃ are each independently selected from aromatic groups having from about 4 to about 20 carbon atoms (for example, substituted or unsubstituted phenyl, naphthyl, thienyl, and furanyl, where substitution can be with such groups as alkoxy, alkylthio, arylthio, halogen, and so forth) and alkyl groups having from 1 to about 20 carbon atoms. As used here, the term “alkyl” includes substituted alkyl (for example, substituted with such groups as halogen, hydroxy, alkoxy, or aryl). At least one of R₁, R₂, and R₃ is aromatic, and, preferably, each is independently aromatic. Z is selected from the group consisting of a covalent bond, oxygen, sulfur, —S(═O)—, —C(═O)—, —(O═)S(═O)—, and —N(R)—, where R is aryl (of about 6 to about 20 carbons, such as phenyl), acyl (of about 2 to about 20 carbons, such as acetyl, benzoyl, and so forth), a carbon-to-carbon bond, or —(R₄—)C(—R₅)—, where R₄ and R₅ are independently selected from the group consisting of hydrogen, alkyl groups having from 1 to about 4 carbon atoms, and alkenyl groups having from about 2 to about 4 carbon atoms. X⁻ is an anion, as described below.

Suitable anions, X⁻, for the sulfonium salts (and for any of the other types of photoinitiators) include a variety of anion types such as, for example, imide, methide, boron-centered, phosphorous-centered, antimony-centered, arsenic-centered, and aluminum-centered anions.

Illustrative, but not limiting, examples of suitable imide and methide anions include (C₂F₅SO₂)₂N⁻, (C₄F₉SO₂)₂N⁻, (C₈F₁₇SO₂)₃C⁻, (CF₃SO₂)₂N—, (C₄F₉SO₂)₃C⁻, (CF₃SO₂)₂(C₄F₉SO₂)C⁻, (CF₃SO₂)(C₄F₉SO₂)⁻, ((CF₃)₂NC₂F₄SO₂)₂N⁻, (CF₃)₂NC₂F₄SO₂C⁻(SO₂CF₃)₂, (3,5-bis(CF₃)C₆H₃)SO₂N⁻SO₂CF₃, C₆H₅SO₂C⁻(SO₂CF₃)₂, C₆H₅SO₂N⁻SO₂CF₃, and the like. Preferred anions of this type include those represented by the formula (R_{f}SO₂)₃C⁻, wherein R_{f} is a perfluoroalkyl radical having from 1 to about 4 carbon atoms.

Illustrative, but not limiting, examples of suitable boron-centered anions include F₄B⁻, (3,5-bis(CF₃)C₆H₃)₄B⁻, (C₆F₅)₄B⁻, (p-CF₃C₆H₄)₄B⁻, (m-CF₃C₆H₄)₄B⁻, (p-FC₆H₄)₄B⁻, (C₆F₅)₃(CH₃)B⁻, (C₆F₅)₃(n-C₄H₉)B⁻, (p-CH₃C₆H₄)₃(C₆F₅)B⁻, (C₆F₅)₃FB⁻, (C₆H₅)₃(C₆F₅)B⁻, (CH₃)₂(p-CF₃C₆H₄)₂B⁻, (C₆F₅)₃(n-C₁₈H₃₇O)B⁻, and the like. Preferred boron-centered anions generally contain 3 or more halogen-substituted aromatic hydrocarbon radicals attached to boron, with fluorine being the most preferred halogen. Illustrative, but not limiting, examples of the preferred anions include (3,5-bis(CF₃)C₆H₃)₄B⁻, (C₆F₅)₄B⁻, (C₆F₅)₃(n-C₄H₉)B⁻, (C₆F₅)₃FB⁻, and (C₆F₅)₃(CH₃)B⁻.

Suitable anions containing other metal or metalloid centers include, for example, (3,5-bis(CF₃)C₆H₃)₄Al⁻, (C₆F₅)₄Al⁻, (C₆F₅)₂F₄P⁻, (C₆F₅)F₅P⁻, F₆P⁻, (C₆F₅)F₅Sb⁻, F₆Sb⁻, (HO)F₅Sb⁻, and F₆As⁻. The foregoing lists are not intended to be exhaustive, as other useful boron-centered non-nucleophilic salts, as well as other useful anions containing other metals or metalloids, will be readily apparent (from the foregoing general formulas) to those skilled in the art.

Preferably, the anion, X⁻, is selected from tetrafluoroborate, hexafluorophosphate, hexafluoroarsenate, hexafluoroantimonate, and hydroxypentafluoroantimonate (for example, for use with cationically-reactive species such as epoxy resins).

Examples of suitable sulfonium salt photoinitiators include: triphenylsulfonium tetrafluoroborate, methyldiphenylsulfonium tetrafluoroborate, dimethylphenylsulfonium hexafluorophosphate, triphenylsulfonium hexafluorophosphate, triphenylsulfonium hexafluoroantimonate, diphenylnaphthylsulfonium hexafluoroarsenate, tritolysulfonium hexafluorophosphate, anisyldiphenylsulfonium hexafluoroantimonate, 4-butoxyphenyldiphenylsulfonium tetrafluoroborate, 4-chlorophenyldiphenylsulfonium hexafluorophosphate, tri(4-phenoxyphenyl)sulfonium hexafluorophosphate, di(4-ethoxyphenyl)methylsulfonium hexafluoroarsenate, 4-acetonylphenyldiphenylsulfonium tetrafluoroborate, 4-thiomethoxyphenyldiphenylsulfonium hexafluorophosphate, di(methoxysulfonylphenyl)methylsulfonium hexafluoroantimonate, di(nitrophenyl)phenylsulfonium hexafluoroantimonate, di(carbomethoxyphenyl)methylsulfonium hexafluorophosphate, 4-acetamidophenyldiphenylsulfonium tetrafluoroborate, dimethylnaphthylsulfonium hexafluorophosphate, trifluoromethyldiphenylsulfonium tetrafluoroborate, p-(phenylthiophenyl)diphenylsulfonium hexafluoroantimonate, 10-methylphenoxathiinium hexafluorophosphate, 5-methylthianthrenium hexafluorophosphate, 10-phenyl-9,9-dimethylthioxanthenium hexafluorophosphate, 10-phenyl-9-oxothioxanthenium tetrafluoroborate, 5-methyl-10-oxothianthrenium tetrafluoroborate, and 5-methyl-10,10-dioxothianthrenium hexafluorophosphate.

Preferred sulfonium salts include triaryl-substituted salts such as triarylsulfonium hexafluoroantimonate (for example, SarCat™ SR1010 available from Sartomer Company), triarylsulfonium hexafluorophosphate (for example, SarCat™ SR 1011 available from Sartomer Company), and triarylsulfonium hexafluorophosphate (for example, SarCat™ KI85 available from Sartomer Company).

Preferred photoinitiators include iodonium salts (more preferably, aryliodonium salts), sulfonium salts, and mixtures thereof. More preferred are aryliodonium salts and mixtures thereof.

### Preparation of Photoreactive Composition

The reactive species, multiphoton photosensitizers, photoinitiators, and, optionally, electron donor compounds can be prepared by the methods described above or by other methods known in the art, and many are commercially available. In certain embodiments, the photoreactive composition may consist essentially of HHA and the photoinitiator system. That is, the photoreactive composition may include HHA, the photoinitiator system, and impurities associated with the use or manufacture of HHA and the photoinitiator system, but may not include any other reactive species or other additives.

The four components can be combined under “safe light” conditions using any order and manner of combination (optionally, with stirring or agitation), although it is sometimes preferable (from a shelf life and thermal stability standpoint) to add the photoinitiator last (and after any heating step that is optionally used to facilitate dissolution of other components). Solvent can be used, if desired, provided that the solvent is chosen so as to not react appreciably with the components of the composition. Suitable solvents include, for example, acetone, dichloromethane, and acetonitrile. The reactive species itself can also sometimes serve as a solvent for the other components.

The three components of the photoinitiator system are present in photochemically effective amounts (as defined above). Generally, the composition can contain at least about 5% (preferably, at least about 10%; more preferably, at least about 20%) up to about 99.79% (preferably, up to about 95%; more preferably, up to about 80%) by weight of one or more reactive species; at least about 0.01% (preferably, at least about 0.1%; more preferably, at least about 0.2%) up to about 10% (preferably, up to about 5%; more preferably, up to about 2%) by weight of one or more photosensitizers; optionally, up to about 10% (preferably, up to about 5%) by weight of one or more electron donor compounds (preferably, at least about 0.1%; more preferably, from about 0.1% to about 5%); and from about 0.1% to about 10% by weight of one or more electron acceptor compounds (preferably, from about 0.1% to about 5%) based upon the total weight of solids (that is, the total weight of components other than solvent).

A wide variety of adjuvants can be included in the photoreactive compositions, depending upon the desired end use. Suitable adjuvants include solvents, diluents, resins, binders, plasticizers, pigments, dyes, inorganic or organic reinforcing or extending fillers (at preferred amounts of about 10% to 90% by weight based on the total weight of the composition), thixotropic agents, indicators, inhibitors, stabilizers, ultraviolet absorbers, and the like. The amounts and types of such adjuvants and their manner of addition to the compositions will be familiar to those skilled in the art.

While not preferred, it is within the scope of this invention to include optional nonreactive polymeric binders in the compositions in order, for example, to control viscosity and to provide film-forming properties. Such polymeric binders can generally be chosen to be compatible with the reactive species. For example, polymeric binders that are soluble in the same solvent that is used for the reactive species, and that are free of functional groups that can adversely affect the course of reaction of the reactive species, can be utilized. Binders can be of a molecular weight suitable to achieve desired film-forming properties and solution rheology (for example, molecular weights between about 5,000 and 1,000,000 Daltons; preferably between about 10,000 and 500,000 Daltons; more preferably, between about 15,000 and 250,000 Daltons). Suitable polymeric binders include, for example, polystyrene, poly(methyl methacrylate), poly(styrene)-co-(acrylonitrile), cellulose acetate butyrate, and the like.

Prior to exposure, the resulting photoreactive compositions can be coated on a substrate, if desired, by any of a variety of coating methods known to those skilled in the art (including, for example, knife coating and spin coating). The substrate can be chosen from a wide variety of films, sheets, and other surfaces (including silicon wafers and glass plates), depending upon the particular application and the method of exposure to be utilized. Prior to coating the substrate with the multiphoton curable photoreactive composition, the substrate may be primed with a suitable compound, such as a compound that includes a silane group and a functional group similar to the photoreactive composition. Suitable primers include, for example, trimethoxysilylpropylmethacrylate (available from Sigma-Aldrich, St. Louis, Mo.), and the like. Preferred substrates are generally sufficiently flat to enable the preparation of a layer of photoreactive composition having a uniform thickness. For applications where coating is less desirable, the photoreactive compositions can alternatively be exposed in bulk form.

### Exposure System and its Use

The above-described multiphoton curable photoreactive composition can be exposed to light under conditions such that multiphoton absorption occurs, thereby causing a region of curing of the composition. Such exposure can be accomplished by any known means capable of achieving sufficient intensity of the light.

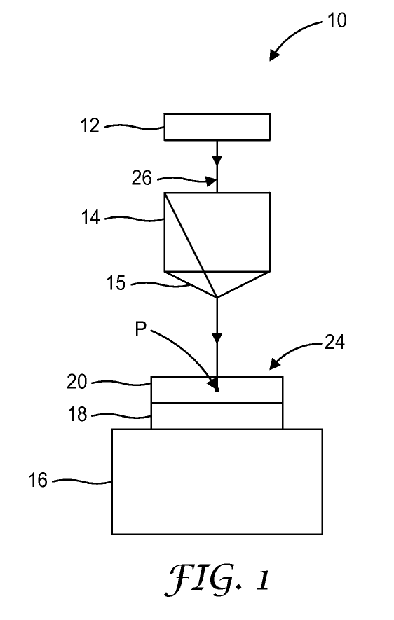

One exemplary type of system that can be used is shown in FIG. 1. Referring to FIG. 1, fabrication system 10 includes light source 12, optical system 14 comprising a final optical element 15 (optionally including galvo-mirrors and a telescope to control beam divergence), and moveable stage 16. Stage 16 is moveable in one, two, or, more typically, three dimensions. Substrate 18 mounted on stage 16 has a layer 20 of multiphoton curable photoreactive composition 24 thereon. Light beam 26 originating from light source 12 passes through optical system 14 and leaves through final optical element 15 which focuses it to a point P within layer 20, thereby controlling the three-dimensional spatial distribution of light intensity within the photoreaction composition 24 and causing at least a portion of photoreactive composition 24 in the vicinity of point P to cure.

By moving stage 16, or by directing light beam 26 (for example, moving a laser beam using galvo-mirrors and a telescope) in combination with moving one or more elements of optical system 14, the focal point P can be scanned or translated in a three-dimensional pattern that corresponds to a desired shape. The resulting cured or partially cured portion of photoreactive composition 24 then creates a three-dimensional structure of the desired shape. For example, in a single pass the surface profile (corresponding to a thickness of about one volume pixel or voxel) of one or more light extraction structures can be exposed or imaged, which upon development can form the surface of the structure(s).

The exposure or imaging of the surface profile can be carried out by scanning at least the perimeter of a planar slice of a desired three-dimensional structure and then scanning a plurality of preferably parallel, planar slices to complete the structure. Slice thickness can be controlled to achieve a sufficiently low level of surface roughness to provide quality structures. For example, smaller slice thicknesses can be desirable in regions of greater structure taper to aid in achieving high structure fidelity, but larger slice thicknesses can be utilized in regions of less structure taper to aid in maintaining useful fabrication times. In this way, a surface roughness less than the slice thickness (preferably, less than about one-half of the slice thickness; more preferably, less than about one-quarter of the slice thickness) can be achieved without sacrificing fabrication speed (throughput or number of structures fabricated per unit time).

When the photoreactive composition 24 is coated on a substrate that exhibits a degree of non-planarity that is of the same or greater size magnitude as voxel height, it can be desirable to compensate for the non-planarity to avoid optically- or physically-defective structures. This can be accomplished by locating (for example, using a confocal interface locator system) the position of the interface between the substrate and the portion of the photoreactive composition that is to be exposed, and then adjusting the location of the optical system 14 appropriately to focus light beam 26 at the interface. (Such a procedure is described in detail in a co-pending patent application bearing Attorney Docket No. 61438US002, the description of which is incorporated herein by reference.) Preferably, this procedure can be followed for at least one structure out of every twenty structures in an array (more preferably, at least one out of every ten; most preferably, for each structure in the array).

Light source 12 can be any light source that produces sufficient light intensity to effect multiphoton absorption. Suitable sources include, for example, ultrafast lasers such as picosecond and femtosecond lasers. For example, suitable femtosecond lasers include near-infrared titanium sapphire oscillators (for example, those available from Coherent, Santa Clara, Calif., under the trade designation “MIRA OPTIMA 900-F”) pumped by an argon ion laser (for example, those available from Coherent under the trade designation “INNOVA”). This laser, operating at 76 MHz, has a pulse width of less than 200 femtoseconds, is tunable between 700 and 980 nm, and has average power up to 1.4 Watts. Another useful laser is available from Spectra-Physics, Mountain View, Calif., under the trade designation “MAI TAI”, tunable to wavelengths in a range of from 750 to 850 nanometers, and having a repetition frequency of 80 megahertz, and a pulse width of about 100 femtoseconds (1×10⁻¹³ sec), with an average power level up to 1 Watt.

However, any light source (for example, a laser) that provides sufficient intensity to effect multiphoton absorption at a wavelength appropriate for the multiphoton absorber used in the photoreactive composition can be utilized. Such wavelengths can generally be in the range of about 300 to about 1500 nm; preferably, from about 400 to about 1100 nm; more preferably, from about 600 to about 900 nm; more preferably, from about 750 to about 850 nm, inclusive. Typically, the light fluence (for example, peak intensity of a pulsed laser) is greater than about 10⁶ W/cm². The upper limit on the light fluence is generally dictated by the ablation threshold of the photoreactive composition. For example, Q-switched Nd:YAG lasers (for example, those available from Spectra-Physics under the trade designation “QUANTA-RAY PRO”), visible wavelength dye lasers (for example, those available from Spectra-Physics under the trade designation “SIRAH” pumped by a Q-switched Nd:YAG laser from Spectra-Physics having the trade designation “Quanta-Ray PRO”), and Q-switched diode pumped lasers (for example, those available from Spectra-Physics under the trade designation “FCBAR”) can also be utilized.

Preferred light sources are near infrared pulsed lasers having a pulse length less than about 10⁻⁸ second (more preferably, less than about 10⁻⁹ second; most preferably, less than about 10⁻¹¹ second). Other pulse lengths can be used as long as the peak intensity and ablation threshold criteria above are met. Pulsed radiation can, for example, have a pulse frequency of from about one kilohertz up to about 50 megahertz, or even more. Continuous wave lasers can also be used.

Optical system 14 can include, for example, refractive optical elements (for example, lenses or microlens arrays), reflective optical elements (for example, retroreflectors or focusing mirrors), diffractive optical elements (for example, gratings, phase masks, and holograms), polarizing optical elements (for example, linear polarizers and waveplates), dispersive optical elements (for example, prisms and gratings), diffusers, Pockels cells, waveguides, and the like. Such optical elements are useful for focusing, beam delivery, beam/mode shaping, pulse shaping, and pulse timing. Generally, combinations of optical elements can be utilized, and other appropriate combinations will be recognized by those skilled in the art. Final optical element 15 can include, for example, acrylate ester (available under the trade name SR-9008, Sartomer Co., Inc., Exton, Pa.) and about 35 wt. % tris-(2-hydroxy ethyl)isocyanurate triacrylate (available under the trade name SR-368, Sartomer, Co., Inc., Exton, Pa.).

Each of the formulations was spin-coated on a double-polished Si wafer that was primed with a thin film (about a monolayer) of trimethoxysilylpropylmethacrylate (available from Sigma-Aldrich, St. Louis, Mo.). The spin-coating was carried out at 1500 rpm for 60 seconds. The coated Si wafer was then baked at 80° C. for about 5 minutes. The resulting coating thicknesses were about 14.6 μm for the HHA sample, and about 17.3 μm for the acrylate sample.

Two-photon photopolymerization was induced by an IMRA Femtolite F100 fiber laser (807.5 nm wavelength, 114 femtosecond pulse width, 77.1 MHz repetition rate, available from IMRA America, Ann Arbor, Mich.) focused through a Zeiss 63X, 1.40 numerical aperture oil immersion objective (Carl Zeiss, North America). Zeiss Immersol 518F immersion oil (n=1.518, Carl Zeiss, North America) was dropped directly on top of the coated silicon wafer and the objective immersed in the oil. Samples were placed on a TRITOR 400CAP (piezosystem jena, Hopedale, Mass.) 3-axis stage with computer control of stage movement and laser beam shuttering. The power delivered to the objective lens was controlled by rotating a ½ waveplate optic placed in the beam path with respect to a polarizing beam splitting cube. The reported average power was measured at the output of the microscope objective using a wavelength calibrated Thorlabs S121B power meter optical head (Thorlabs, Newton, N.J.). The photopolymer-substrate interface location was determined by observing the 807.5 nm reflection maximum with an Ocean Optics USB2000 spectrometer (Ocean Optics, Dunedin, Fla.) as a function of z-axis height.

Test structures consisted of polymer bridges held between solid polymer support structures and suspended about 12 μm above the substrate. The suspended lines were written at scan velocities from 36.5 μm/s to 141.4 μm/s and constant power, increasing the scan velocity by the square root of two for each line. After two photon exposure, the sample was developed in propylene glycol methyl ether acetate (PGMEA) for about 3 minutes to remove the uncured polymer and then air dried. Scanning electron microscope (SEM) images were used to measure line width and height, and cross-sectional areas and aspect ratios were computed using these measured dimensions. one or more refractive, reflective, and/or diffractive optical elements. In one embodiment, an objective such as, for example, those used in microscopy can be conveniently obtained from commercial sources such as, for example, Carl Zeiss, North America, Thornwood, N.Y., and used as final optical element 15. For example, fabrication system 10 can include a scanning confocal microscope (for example, those available from Bio-Rad Laboratories, Hercules, Calif., under the trade designation “MRC600”) equipped with a 0.75 numerical aperture (NA) objective (such as, for example, those available from Carl Zeiss, North America under the trade designation “20X FLUAR”).

It can often be desirable to use optics with relatively large numerical aperture to provide highly-focused light. However, any combination of optical elements that provides a desired intensity profile (and spatial placement thereof) can be utilized.

Exposure times generally depend upon the type of exposure system used to cause reaction of the reactive species in the photoreactive composition (and its accompanying variables such as numerical aperture, geometry of light intensity spatial distribution, the peak light intensity during the laser pulse (higher intensity and shorter pulse duration roughly correspond to peak light intensity)), as well as upon the nature of the photoreactive composition. Generally, higher peak light intensity in the regions of focus allows shorter exposure times, everything else being equal. Linear imaging or “writing” speeds generally can be about 5 to 100,000 microns/second using a laser pulse duration of about 10⁻⁸ to 10⁻¹⁵ second (for example, about 10⁻¹¹ to 10⁻¹⁴ second) and about 10² to 10⁹ pulses per second (for example, about 10³ to 10⁸ pulses per second).

In order to facilitate solvent development of the exposed photoreactive composition and obtain a fabricated structure, a threshold dose of light (that is, threshold dose) can be utilized. This threshold dose is typically process specific, and can depend on variables such as, for example, the wavelength, pulse frequency, intensity of the light, the specific photoreactive composition, the specific structure being fabricated, or the process used for solvent development. Thus, each set of process parameters can typically be characterized by a threshold dose. Higher doses of light than the threshold can be used, and can be beneficial, but higher doses (once above the threshold dose) can typically require a slower writing speed and/or higher light intensity.

Increasing the dose of light tends to increase the volume and aspect ratio of voxels generated by the process. Thus, in order to obtain voxels of low aspect ratio, it is generally preferable to use a light dose that is less than about 10 times the threshold dose, preferably less than about 4 times the threshold dose, and more preferably less than about 3 times the threshold dose. In order to obtain voxels of low aspect ratio, the radial intensity profile of light beam 26 is preferably Gaussian.

Through multiphoton absorption, light beam 26 induces a reaction in the photoreactive composition that produces a volume region of cured material. The resulting pattern of cured and uncured material can then be realized by a conventional development process, for example, by removing uncured regions.

The at least partially cured photoreactive composition can be developed, for example, by placing the at least partially cured photoreactive composition into solvent to dissolve regions of uncured material, by rinsing with solvent, by evaporation, by oxygen plasma etching, by other known methods, and by combinations thereof. Solvents that can be used to develop the at least partially cured photoreactive composition include, for example, propylene glycol methyl ether acetate (PGMEA).

Optionally, after exposure of only the surface profile of a desired structure, preferably followed by solvent development, a nonimagewise exposure using actinic radiation can be carried out to effect reaction of the remaining unreacted photoreactive composition. Such a nonimagewise exposure can preferably be carried out by using a one-photon process.

Complex three-dimensional structures and structure arrays can be prepared in this manner.

### EXAMPLES

Various embodiments will now be described in reference to the following examples. These examples are provided for illustrative purposes, and are not intended to be taken as limiting in any manner.

### Example 1

### Preparation of 1,3-Bis(3-[2,2,2-(triacryloyloxymethyl)ethoxy-2-hydroxypropyl]-5,5-dimethyl-2,4-imidizolidinedione (Hydantoin Hexaacrylate)

Pentaerythritol triacrylate (44.3 g, 0.1 m, hydroxyl equivalent weight of 443), 0.025 g 4-methoxyphenol, and 0.4 g borontrifluoride etherate were charged into a 250 ml three-necked round bottom flask equipped with a mechanical stirrer, pressure equalizing dropping funnel, reflux condenser, and a CaSO₄ drying tube. The reaction flask was heated to 60° C. and 13.8 g of 1,3-bis(2,3-epoxypropyl)-5,5-dimethyl-2,4-imidizolidinedione (0.1 m epoxide equivalency) in 5 ml chloroform was added dropwise over 45 minutes. After the addition, the reaction flask temperature was raised to 85° C. and stirred to 11.5 hours. After this time, titration of an aliquote for unreacted epoxide indicated that the reaction was greater than 99% complete. The chloroform was removed by vacuum distillation leaving as residue a viscous liquid that contains predominantly compounds of the structure of Compound A. Photocurable impurities introduced with the pentaerythritol triacrylate can be removed by trituration with diethyl ether.

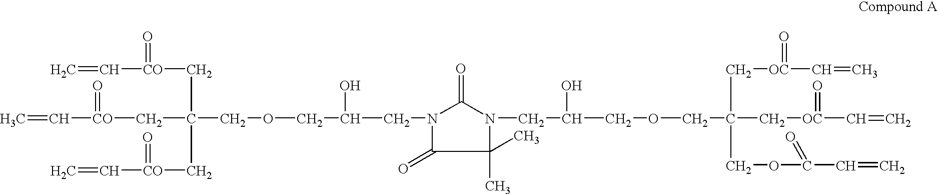

Further details on HHA and the preparation thereof can be found in commonly assigned U.S. Pat. No. 4,249,011 to Wendling, which is incorporated herein by reference in its entirety.

### Example 2

A multiphoton curable photoreactive composition of the current invention was prepared as follows: 20 g hydantoin hexaacrylate (HHA), 0.98 g tris[4-(7-benzothiazol-2-yl-9,9-diethylfluoren-2-yl)phenyl]amine (AF-350), 0.196 g diaryliodonium hexafluoroantimonate (available under the tradename SarCat™ CD-1012, Sartomer Co., Inc., Exton, Pa.) were dissolved in 6.49 g cyclopentanone. The solution was then filtered through a 0.75 μm glass filter, producing a solution with about 74 wt. % solids content.

For comparative purposes, a typical acrylate multiphoton curable photoreactive composition was prepared. First, 0.05 g AF-350 and 0.11 g SR-1012 were dissolved in 0.56 g cyclopentanone. This solution was then filtered through a 0.75 μm glass filter and added to 20 g of a stock solution. The stock solution contained about 30 wt. % PMMA (Mₙ=120,000 g/mol, Sigma-Aldrich, St. Louis, Mo.), about 35 wt. % alkoxylated trifunctional

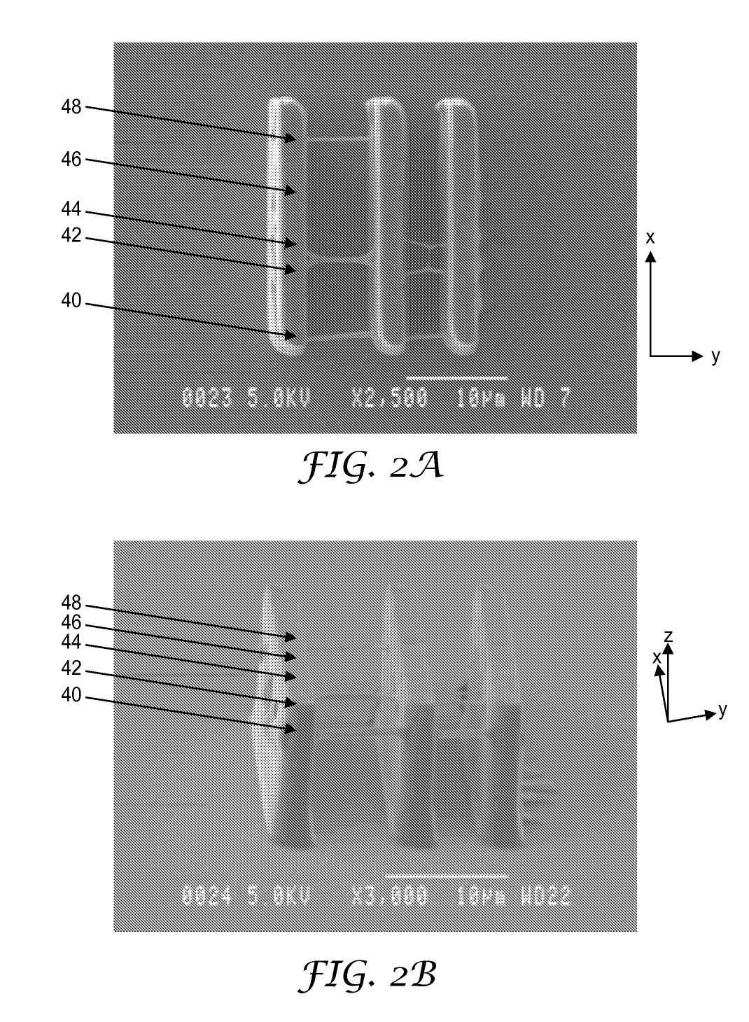

Table 1 shows the results of the scans with an average laser power of 0.5 mW. FIGS. 2A and 2B show the structures formed with the typical acrylate composition. FIG. 2A is an overhead view of the structures, and FIG. 2B is a perspective view of the same structures. Bridge 40 was formed at a scan speed of 36.5 μm/s, bridge 42 was formed at a scan speed of 50.0 μm/s, bridge 44 was formed at a scan speed of 70.7 μm/s, and bridge 48 was formed at a scan speed of 141.1 μm/s.

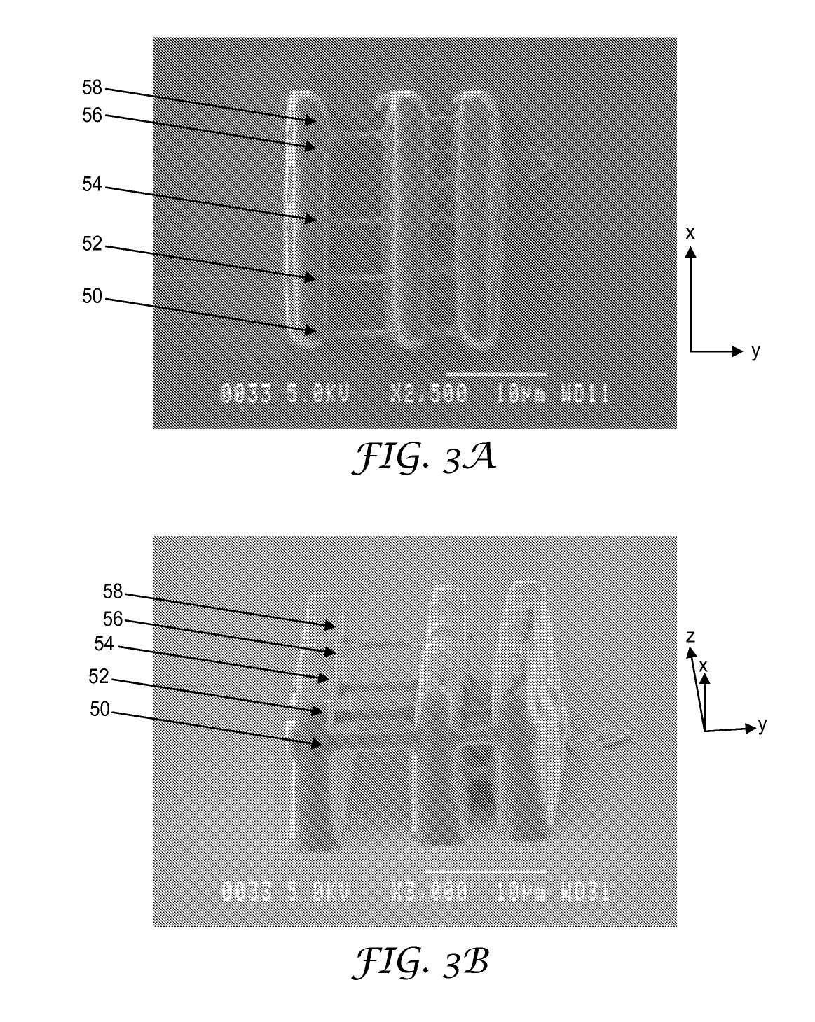

Similarly, FIGS. 3A and 3B show the structures formed with the HHA composition. FIG. 3A is an overhead view of the structures, and FIG. 3B is a perspective view of the same structures. Bridge 50 was formed at a scan speed of 36.5 μm/s, bridge 52 was formed at a scan speed of 50.0 μm/s, bridge 54 was formed at a scan speed of 70.7 μm/s, bridge 56 was formed at a scan speed of 100.0 μm/s, and bridge 58 was formed at a scan speed of 141.1 μm/s.

TABLE 1

| | | | | | Cross- | |
|---|---|---|---|---|---|---|
| | | Scan | Top | Side | sectional | |
| Sample | Reference | Speed | Width | Width | Area | Aspect |
| Name | Numeral | (μm/s) | (μm) | (μm) | (μm²) | Ratio |
| Acrylate | 40 | 36.5 | 0.58 | 0.83 | 0.48 | 1.4 |
| HHA | 50 | 36.5 | 0.64 | 1.7 | 1.1 | 2.7 |
| Acrylate | 42 | 50.0 | — | — | — | — |
| HHA | 52 | 50.0 | 0.58 | 0.91 | 0.53 | 1.6 |
| Acrylate | 44 | 70.7 | — | — | — | — |
| HHA | 54 | 70.7 | ~0.5 | ~0.8 | ~0.4 | ~1.6 |
| Acrylate | 46 | 100.0 | — | — | — | — |
| HHA | 56 | 100.0 | — | — | — | — |
| Acrylate | 48 | 141.1 | — | — | — | — |
| HHA | 58 | 141.1 | — | — | — | — |

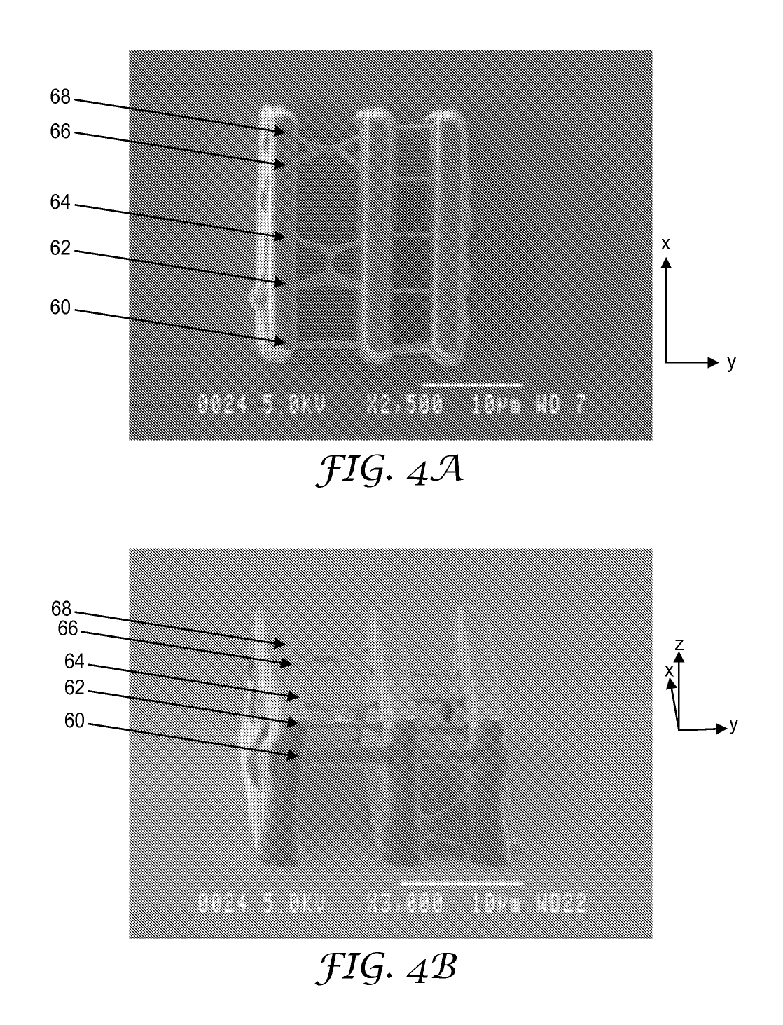

Table 2 shows the results of the scans with an average laser power of 0.7 mW. FIGS. 4A and 4B show the structures formed with the typical acrylate composition at an average laser power of 0.7 mW. FIG. 4A is an overhead view of the structures, and FIG. 4B is a perspective view of the same structures. Bridge 60 was formed at a scan speed of 36.5 μm/s, bridge 62 was formed at a scan speed of 50.0 μm/s, bridge 64 was formed at a scan speed of 70.7 μm/s, bridge 66 was formed at a scan speed of 100.0 μm/s, and bridge 48 was formed at a scan speed of 141.1 μm/s.

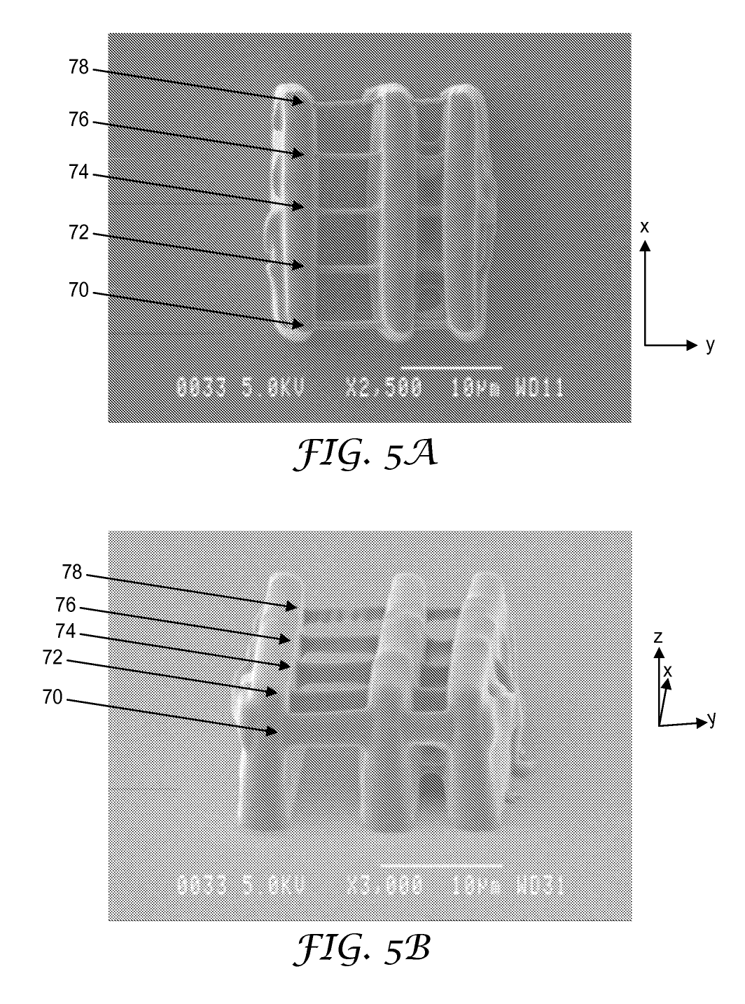

Similarly, FIGS. 5A and 5B show the structures formed with the HHA composition at an average laser power of 0.7 mW. FIG. 5A is an overhead view of the structures, and FIG. 5B is a perspective view of the same structures. Bridge 70 was formed at a scan speed of 36.5 μm/s, bridge 72 was formed at a scan speed of 50.0 μm/s, bridge 74 was formed at a scan speed of 70.7 μm/s, bridge 76 was formed at a scan speed of 100.0 μm/s, and bridge 78 was formed at a scan speed of 141.1 μm/s.

TABLE 2

| | | | | | Cross- | |
|---|---|---|---|---|---|---|
| | | Scan | Top | Side | sectional | |
| Sample | Reference | Speed | Width | Width | Area | Aspect |
| Name | Numeral | (μm/s) | (μm) | (μm) | (μm²) | Ratio |
| Acrylate | 60 | 36.5 | 0.66 | 1.7 | 1.1 | 2.6 |
| HHA | 70 | 36.5 | 0.68 | 3.4 | 2.3 | 5.0 |
| Acrylate | 62 | 50.0 | ~0.5 | — | — | — |
| HHA | 72 | 50.0 | 0.63 | ~1.7 | ~1.1 | ~2.7 |
| Acrylate | 64 | 70.7 | ~0.5 | — | — | — |
| HHA | 74 | 70.7 | 0.53 | 1.5 | 0.8 | 2.8 |
| Acrylate | 66 | 100.0 | ~0.5 | — | — | — |
| HHA | 76 | 100.0 | 0.53 | 4.2 | 0.64 | 2.3 |
| Acrylate | 68 | 141.1 | ~0.3 | — | — | — |
| HHA | 78 | 141.1 | 0.39 | 0.91 | 0.36 | 2.3 |

Dashed lines in the tables indicate bridges for which measurements of the width and/or height were not made. While not wishing to be bound by any theory, there is at least a reason for the inability to make measurements of a given bridge. First, as can be seen, for example, in bridges 42 and 44, a bridge may have swollen during solvent development, come into contact with an adjacent bridge, and become welded to the adjacent bridge. This may occur, for example, when the reactive species does not fully cure upon exposure to the light source, or when the cured reactive species acts as a “solvent” for the developing solvent. This welding to an adjacent bridge also requires sufficiently low tensile strength, or alternatively, sufficiently high elasticity, so that the bridge may deform during solvent development and contact an adjacent bridge. This also occurred for bridges 56 and 58, 62 and 64, and 66 and 68.

A bridge also apparently broke during solvent development. For example, an area corresponding to a bridge was exposed to the light beam at the location referred to by numeral 46. However, upon solvent development, the bridge disappeared, apparently due to insufficient strength or durability upon cure. The forces due to solvent flow and the like during development were apparently too great for bridge 46, and it was broken.

Solvent swelling also contributed to another reason that a measurement was not made. In this case, bridge 48 swelled due to absorption of the solvent during development. Bridge 48 neither failed nor contacted another bridge, but it is apparent in FIG. 2A that the cross-sectional area is not constant along the length of bridge 48. This is unacceptable when forming high fidelity structures on the desired size scale; thus, a measurement was not made.

FIGS. 3A and 3B show bridges formed from the HHA composition at scan rates corresponding to those used on the acrylate blend in FIGS. 2A and 2B. It is apparent when comparing bridges formed at equal scan rates that HHA possesses higher photosensitivity, and/or, upon curing, greater strength and robustness than the acrylate blend. For example, bridge 52 corresponds to a scan rate of 71.7 μm/s. Bridge 52 was formed with high fidelity to the desired structure, while bridge 42, corresponding to a scan rate of 71.7 μm/s in the acrylate blend, deformed during development and welded to bridge 44. A similar scenario also occurred at a scan rate of 100.0 μm/s, where bridge 54 was formed with high fidelity to the desired structure, while bridge 44 deformed and welded to bridge 42 during solvent development.

Bridges 56 and 58 apparently swelled during solvent development, deformed, and welded to each other. This may indicate the light intensity is approaching or is slightly below the threshold intensity, which resulted in partially cured structures that absorbed solvent and deformed during solvent development.

FIGS. 4A, 4B, 5A and 5B show results substantially analogous to FIGS. 2A, 2B, 3A and 3B. For example, bridges 62 and 64, and bridges 66 and 68, all formed by the acrylate blend, swelled, deformed and welded together during solvent development. However, bridges 72, 74, and 76, formed by the HHA composition, maintained high fidelity to the desired structures, while bridge 78 swelled, but did not deform, during solvent development.

The cross-sectional area and aspect ratio of the bridges provide indications of the relative photosensitivity of HHA and the acrylate blend. For example, at a given scan rate and laser power, a larger cross-sectional area indicates higher photosensitivity. Similarly, a higher aspect ratio, that is, a higher ratio of a bridge's height (along the z-axis, normal to the substrate) to its width (along the x-axis, parallel to the substrate), at a given laser power and scan speed implies a higher photosensitivity. As can be seen by comparing the aspect ratios of bridges 40 and 50 and bridges 60 and 70, HHA has a cross-sectional area that is more than double that of the acrylate blend, and an aspect ratio nearly double that of the acrylate blend. Accordingly, HHA is more photosensitive than the typical acrylate blend.

Additionally, the fact that bridges formed by HHA deformed less than bridges formed by the acrylate blend at the same laser power and scan rate (see, for example, bridges 62 and 72) indicates that cured HHA provides greater strength and durability than the cured acrylate blend.

### Example 3

A circular silicon wafer (10.2 cm (4 inches) in diameter; obtained from Wafer World, Inc., West Palm Beach, Fla.) is cleaned by soaking it for approximately ten minutes in a 3:1 volume/volume (v/v) mixture of concentrated sulfuric acid and 30 weight percent aqueous hydrogen peroxide. The wafer is then rinsed with deionized water and followed by isopropanol, after which it is dried under a stream of air. The substrate surface is treated with a silylating agent, which is prepared by mixing 50 mL of 190 proof ethanol, 3 drops of glacial acetic acid and 1 mL of 3-(trimethoxysilylpropyl methacrylate). This solution is poured onto the substrate and allowed to sit for 1 minute. The substrate is then rinsed in 200 proof ethanol and dried at 105° C. for 4 minutes. The wafer is then placed on a hot plate at 200° C. for 1 minute to dry.

A copolymer of 4,4-dimethyl-2-vinyl-2-oxazolin-5-one (VDM) and (2-methacryloxyethyl)-1-hexadecyldimethylammonium bromide (3:1) is prepared and functionalized with 70% (of VDM equivalents) hydroxyethyl methacrylate, 20% tropic acid, and 10% water (to hydrolyze VDM) as described in U.S. Pat. No. 5,235,015. A stock solution of the copolymer is prepared by mixing 1 g of the functionalized copolymer and 2 g methyl ethyl ketone (MEK). The resulting oligomer may have a wide range of molecular weights, and as long as the molecular weight is greater than about 2,000 g/mol, the functionality is expected to be 6 or greater. The molecular weight of the oligomer may be as high as 10,000 g/mol, or even 100,000 g/mol, which may correspond to an expected functionality of at least about 30, and at least about 300, respectively.

A concentrated solution of photosensitizer dye N,N,N-tris(7-(2-benzothiazolyl)-9,9-diethyl-2-fluorenyl)amine (described, along with its synthesis, in Example 20 of U.S. Pat. No. 6,300,502 (Kannan et al.)) and SR1012 in cyclopentanone (available from Lancaster Synthesis, Windham, N.H.) is prepared. The solution is syringed through a 0.2 micrometer (μm) polytetrafluoroethylene (PTFE) filter cartridge and added to the functionalized copolymer solution in MEK to make a solution of 0.5% photosensitizer dye and 1.0% SR-1012 (based upon total weight of solids). The resulting solution is then filtered through a 1.0 μm glass fiber filter and then a 0.7 μm glass fiber filter.

The filtered solution is poured into a 5 cm×5 cm (interior dimensions) area masked with a green gasket tape on the primed silicon wafer. The wafer is allowed to dry at room temperature for about 60 hours and then placed in a forced air oven for 30 minutes at 65° C., followed by 90 minutes at 95° C., followed by 30 minutes at 65° C. to afford a coated silicon wafer with a substantially solvent-free (hereinafter, “dry”) coating thickness of approximately 300 μm.

The backside of the wafer is cleaned with isopropyl alcohol to remove any debris. The wafer is then mounted on a porous carbon vacuum chuck (flatness <1 μm).

A two-photon fabrication system is then activated to produce an optical signal that is stationary in the vertical position (i.e., the fabrication system is not activating the z-control to move the signal in the vertical direction). The signal is used as a detection mechanism to produce a reflection off of the wafer surface in conjunction with a confocal microscope system such that the only condition that would produce a confocal response would occur when the optical signal was focused on the surface of the wafer. The system is aligned to the interface between the coating of photosensitive material and the wafer in the vertical direction.

Two-photon polymerization of the dry coating is carried out in the following manner, using a diode-pumped Ti:sapphire laser (Spectra-Physics, Mountain View, Calif.) operating at a wavelength of 800 nm, nominal pulse width of 80 fs, pulse repetition rate of 80 MHz, and average power of approximately 1 W. The coated wafer is placed on a computer-controllable three-axis stage (obtained from Aerotech, Inc., Pittsburgh, Pa.). The laser beam is attenuated by neutral density filters and is focused into the dry coating using a galvoscanner with telescope for x, y, and z-axis control (available from Nutfield Technology, Inc., Windham, N.H.) and a lens (Nikon CFI Plan Achromat 50X oil objective N.A. 0.90, working distance 0.400 mm, 4.0 mm focal length), which is applied directly on the surface of the dry coating. The average power is measured at the output of the objective lens using a wavelength-calibrated photodiode (obtained from Ophir Optronics, Ltd., Wilmington, Mass.) and is determined to be approximately 9 mW.

A software file that is produced using a CAD program (AUTODESK INVENTOR available from Autodesk, San Raphael, Calif.) and that describes a truncated cone structure is then loaded into the laser scanning software of the two-photon fabrication system. The scanning software slices the prescribed structure into planes with a vertical separation sufficiently small to result in a final polymerized array of structures with low surface roughness. The slice thickness is chosen in the software to be 500 nm, and each planar slice is cross-hatched with hatch spacing of 2 microns to provide a substantially fully cured structure. The system is then activated to scan the laser beam to polymerize the coating of photosensitive material to define the truncated cone structures. The system is operated in an automated fashion to place structures (in the form of truncated cones) at prescribed positions. The resulting cured array is subsequently developed using a stirred solution of 0.1 N aqueous sodium bicarbonate (pH 8.4) for approximately 90 minutes. Microscopic observation of the developed film shows the presence of truncated cones formed of the photosensitive material on the silicon wafer.

The referenced descriptions contained in the patents, patent documents, and publications cited herein are incorporated by reference in their entirety as if each were individually incorporated. Various unforeseeable modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only. These and other embodiments are within the scope of the following claims.

1. A multiphoton curable photoreactive composition comprising:
hydantoin hexaacrylate; and
a photoinitiator system.

2. The composition of claim 1, wherein the photoinitiator system comprises at least one multiphoton photosensitizer, at least one photoinitiator (or electron acceptor), and, optionally, at least one electron donor.

3. A multiphoton curable photoreactive composition consisting essentially of:
hydantoin hexaacrylate; and
a photoinitiator system.

4. The composition of claim 3, wherein the photoinitiator system comprises at least one multiphoton photosensitizer, at least one photoinitiator (or electron acceptor), and, optionally, at least one electron donor.

5. A method comprising:
applying a multiphoton curable photoreactive composition comprising hydantoin hexaacrylate and a photoinitiator system to a substrate; and
at least partially curing a portion of the multiphoton curable photoreactive composition using a multiphoton induced curing process to form an at least partially cured structure.

6. The method of claim 5, wherein the photoinitiator system comprises at least one multiphoton photosensitizer, at least one photoinitiator (or electron acceptor), and, optionally, at least one electron donor.

7. The method of claim 5, further comprising:
developing the at least partially cured structure by removing at least a portion of any uncured multiphoton curable photoreactive composition.

8. The composition of claim 2, wherein the at least one multiphoton photosensitizer is present in an amount up to 10% based on a total weight of solids in the composition and the electron acceptor in an amount up to 10% based on the total weight of solids in the composition.
